(19) United States
(12) Patent Application Publication
(10) Pub. No.: US 2006/0175637 A1
(43) Pub. Date: Aug. 10, 2006

(54) Power line layouts of a macro cell and combined layouts of a macro cell and a power mesh

(75) Inventor: Chan-Ho Lee, Gyeonggi-do (KR)

Correspondence Address: D. Scott Moore;Myers Bigel Sibley & Sajovec, Post Office Box 37428, Raleigh, NC, 27627, US

(73) Assignee: Samsung Electronics Co., Ltd.

(21) Appl. No.: 11/348,802

(22) Filed: Feb. 7, 2006

(30) Foreign Application Priority Data
Feb. 7, 2005 (KR) 2005-11115

(51) Int. Cl. H01L 27/10

(52) U.S. Cl. 257/207

(57) ABSTRACT

A power line layout of a macro cell includes power lines arranged on a plane of the macro cell in a diagonal direction. A combined layout of a macro cell and a power mesh includes a power mesh on which first power lines are formed in a vertical direction and a macro cell having internal circuit elements on which second power lines for providing a power voltage to the plurality of internal circuit elements are formed in a diagonal direction. The first power lines are electrically coupled to the second power lines at intersections between the first and second power lines when the macro cell is arranged to overlap with the power mesh. Accordingly, when the power lines of the macro cell are combined with the power lines of the power mesh, the intersections between the power lines of the macro cell and the power mesh may be easily formed.

### CROSS REFERENCE TO RELATED APPLICATION

This application claims priority to Korean Patent Application No. 2005-11115 filed on Feb. 7, 2005 in the Korean Intellectual Property Office, the entire contents of which are hereby incorporated by reference.

### BACKGROUND OF THE INVENTION

1. Field of the Invention

The present invention relates generally to integrated circuit design and, more particularly, power line layout in integrated circuits.

2. Description of the Related Art

Recently, as digital devices have been developed and popularized, demand for highly integrated systems has increased. A System-on-Chip (SoC) has become an important design technique for manufacturing semiconductor integrated circuit chips.

Typically, a layout of these semiconductor integrated circuit chips includes an internal cell area and an input/output (IO) cell area. The internal cell area typically includes a plurality of primitive cells and a plurality of macro cells.

The primitive cell refers to an electric element that is the smallest unit used for implementing the semiconductor integrated circuit chip, and the primitive cell may include an inverter, a buffer, a latch, a flip-flop and/or logic gates such as NAND, OR, NOR, etc.

The macro cell refers to a unit of a cell used for implementing the semiconductor integrated circuit chip. The macro cell may include the primitive cell within the macro cell itself and has a cell layout for itself. For example, the macro cell may include memory devices, a phase-locked loop (PLL), an analog-to-digital converter (ADC), a digital-to-analog converter (DAC) and/or a coder/decoder (CODEC).

Complex lines may be formed so as to respectively power circuit elements in the macro cell. The complexity may result in a reduction in productivity and density of an integrated circuit. Therefore, to improve productivity and integrity of the semiconductor integrated circuit chip, the macro cell may be combined with a power mesh on which a plurality of standardized power lines is formed.

FIG. 1 is a wiring diagram illustrating a planar power line layout of a conventional macro cell. Referring to FIG. 1, the power line of the conventional macro cell 10 includes a plurality of VDD lines 12 and a plurality of VSS lines 14. The VSS lines 14 are spaced apart from the VDD lines 12 by a predetermined distance. That is, the VDD lines 12 and the VSS lines 14 are alternately arranged in parallel with each other in a horizontal direction.

However, because the power line of the macro cell 10 may have a rotated form according to some manufacturing methods, the VDD line 12 and the VSS line 14 may be alternately arranged in parallel with each other in a horizontal direction or a vertical direction.

FIG. 2 is a wiring diagram illustrating a planar power line layout of a conventional power mesh. Referring to FIG. 2, the power mesh 20 includes a plurality of VDD lines 22 and a plurality of VSS lines 24. The VSS lines 24 are spaced apart from the VDD lines 22 by a predetermined distance. The VDD lines 22 and the VSS lines 24 are alternately arranged in parallel with each other in a vertical direction. A power voltage is applied to the VDD lines 22 from an external power source, and then the power voltage applied to the VDD lines 22 is coupled to the VDD lines 12 of the macro cell 10 shown in FIG. 1.

FIG. 3 is a wiring diagram illustrating a power line layout of a conventional macro cell 10 shown in FIG. 1 overlaid by a conventional power mesh 20 shown in FIG. 2. Referring to FIG. 3, the VDD lines 12 and the VSS lines 14 of the macro cell 10 are arranged in parallel with each other in a horizontal direction, and the VDD lines 22 and the VSS lines 24 of the power mesh 20 are arranged in parallel with each other in a vertical direction. Accordingly, the power lines 12,14 of the macro cell 10 and the power lines 22, 24 of the power mesh 20 placed in an upper layer of the macro cell 10 are orthogonal to each other.

That is, VDD intersections 32 are formed between the VDD lines 12 of the macro cell 10 and the VDD lines 22 of the power mesh 20 that is placed on the upper layer of the macro cell 10, and VSS intersections 34 are formed between the VSS lines 14 of the macro cell 10 and the VSS lines 24 of the power mesh 20 that is placed on the upper layer of the macro cell 10.

The upper layer and the lower layer are coupled at the intersections 32 and 34 through a via-connection. The via-connection refers to a stack type connection between the upper layer and the lower layer. Therefore, the VDD lines 12 of the macro cell 10 and the VDD lines 22 of the power mesh 20 may be electrically coupled to each other, thereby enabling power to be supplied to the macro cell 10.

Accordingly, it is not necessary to set a special wiring for providing the power voltage to the macro cell 10; hence, the power voltage may provided because a routing space for wiring of various circuits may be secured and a simple circuit structure may be achieved.

An actual manufacturing process, however, includes not only the orthogonal layout shown in FIG. 3 but also a rotated layout in which the macro cell 10 is rotated from the orthogonal direction.

FIG. 4 is a wiring diagram illustrating a power line layout of a conventional macro cell 10 that is rotated by 90 degrees in a counterclockwise direction compared with FIG. 1, overlaid by a conventional power mesh 20 shown in FIG. 2.

Referring to FIG. 4, the macro cell 10 is rotated 90-degrees in the counterclockwise direction on the macro cell 10 shown in FIG. 1. As a result, the VDD lines 12 and the VSS lines 14 of the macro cell 10 shown in FIG. 4 are alternately arranged in parallel with each other in a vertical direction. In addition, the VDD lines 22 and the VSS lines 24 of the power mesh 20 are alternately arranged in parallel with each other in the vertical direction.

Accordingly, the power lines 12 and 14 of the macro cell 10 are parallel to the power lines 22 and 24 of the power mesh 20, which is placed on the upper layer of the macro cell 10, in a plane view.

Due to the parallel layout of the power lines 12 and 14 of the macro cell 10 and the power lines 22 and 24 of the power mesh 20, the VDD intersections 32 between the VDD lines 12 of the macro cell 0 and the VDD lines 22 of the power mesh 20 may not be formed.

Similarly, the VSS intersections 34 between the VSS lines 14 of the macro cell 10 and the VSS lines 24 of the power mesh 20 may not be formed.

Such cases use connection lines 36 for specially connecting the VDD line 12a of the macro cell 10 to the VDD line 22a of the power mesh 20, and connecting the VSS line 14a of the macro cell 10 to the VSS line 24a of the power mesh 20. These connection lines 36 may reduce the routing resources used for other wirings except the wiring for providing the power voltage.

Moreover, when the VDD lines 12 of the macro cell 10 overlaps with the VSS lines 22 of the power mesh 20 and/or when the VSS lines 14 of the macro cell 10 overlaps with the VDD lines 24 of the power mesh 20, a connection defect may occur. The above-described problems, including the addition of the connection lines 36 and the connection defects, may place limitations on a circuit design and layout of the SoC. Recently, two-type layouts using two macro cells have been proposed; however, the two-type layouts using two macro cells still have various problems associated therewith.

### SUMMARY

According to some embodiments of the present invention, a power line layout of a macro cell includes a plurality of power lines arranged on a plane of the macro cell in a diagonal direction such that the power lines are substantially parallel with a line defined by two non-adjacent corners of the plane.

In other embodiments of the present invention, the power lines include VDD lines and VSS lines that alternate with respect to each other.

In still other embodiments of the present invention, the power lines are substantially parallel to each other.

In still other embodiments of the present invention, a distance between the power lines is substantially uniform.

In still other embodiments of the present invention, the macro cell has a tetragonal shape.

In still other embodiments of the present invention, the power lines include a center power line formed from a first vertex of the macro cell to a second vertex, non-adjacent to the first vertex, in a diagonal direction. Other power lines are spaced apart from both sides of the center power line by a predetermined distance and are substantially parallel with the center power line.

In still other embodiments of the present invention, the power lines have a stair configuration having a plurality of step heights.

In still other embodiments of the present invention, the step heights are substantially equal.

In still other embodiments of the present invention, the stair configuration has an orthogonal shape of which an interior angle is about 90 degrees.

In further embodiments of the present invention, a combined layout of a macro cell and a power mesh includes a power mesh including a plurality of first power lines arranged a first direction. A macro cell includes a plurality of internal circuit elements and a plurality of second power lines for providing a power voltage to the plurality of internal circuit elements. The plurality of second power lines are arranged on a plane of the macro cell in a diagonal direction such that the power lines are substantially parallel with a line defined by two non-adjacent corners of the plane. The first power lines are electrically coupled to the second power lines at intersections between the first power lines of the power mesh and the second power lines of the macro cell.

### BRIEF DESCRIPTION OF THE DRAWINGS

Other features of the present invention will be more readily understood from the following detailed description of specific embodiments thereof when read in conjunction with the accompanying drawings, in which:

FIG. 1 is a wiring diagram illustrating a planar power line layout of a conventional macro cell;

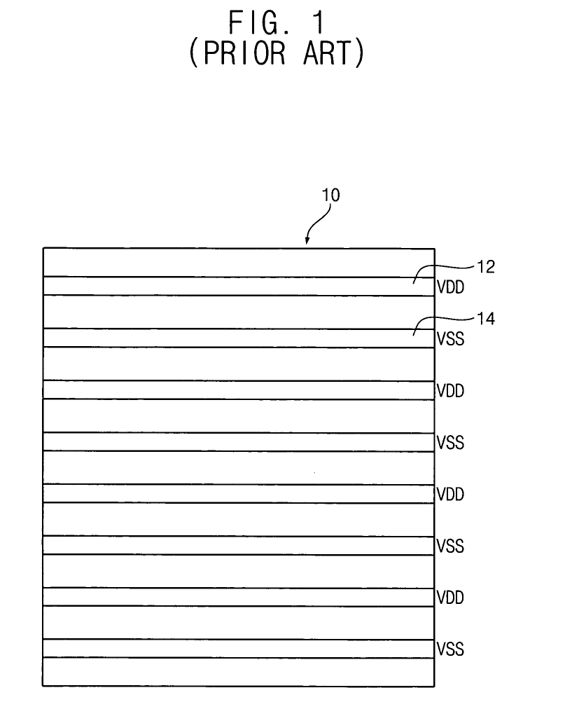

FIG. 2 is a wiring diagram illustrating a planar power line layout of a conventional power mesh;

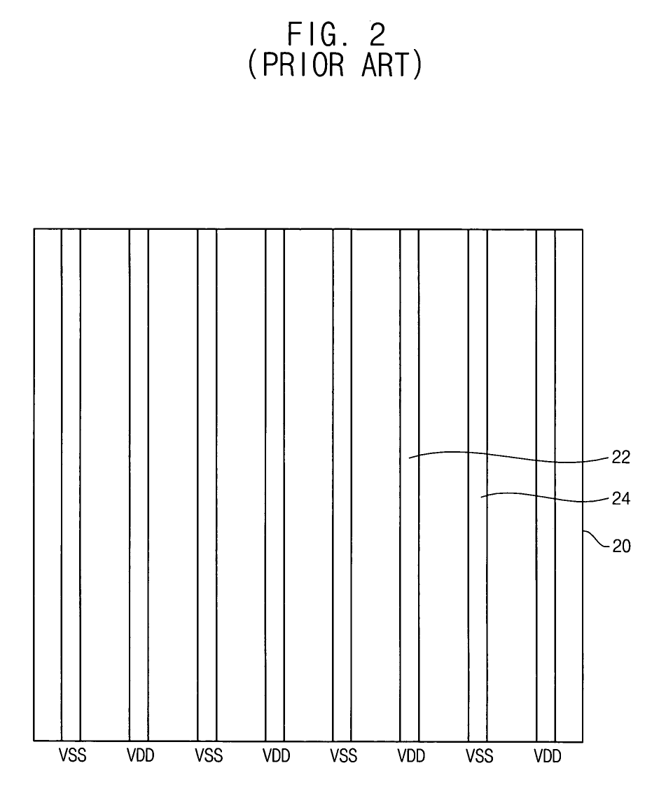

FIG. 3 is a wiring diagram illustrating a power line layout of a conventional macro cell shown in FIG. 1 overlaid by the conventional power mesh shown in FIG. 2;

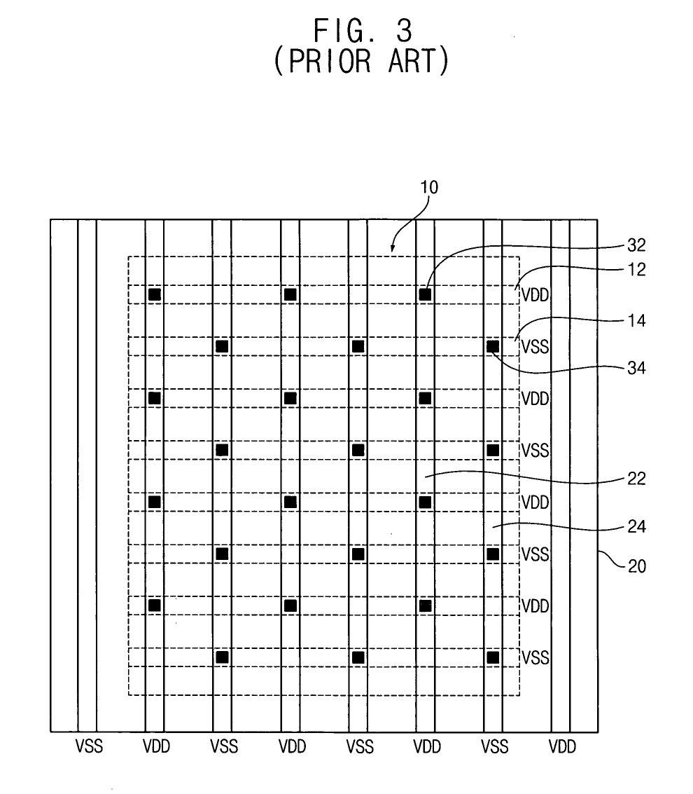

FIG. 4 is a wiring diagram illustrating a power line layout of a conventional macro cell that is rotated by 90 degrees in a counterclockwise direction compared with FIG. 1 overlaid by the conventional power mesh shown in FIG. 2;

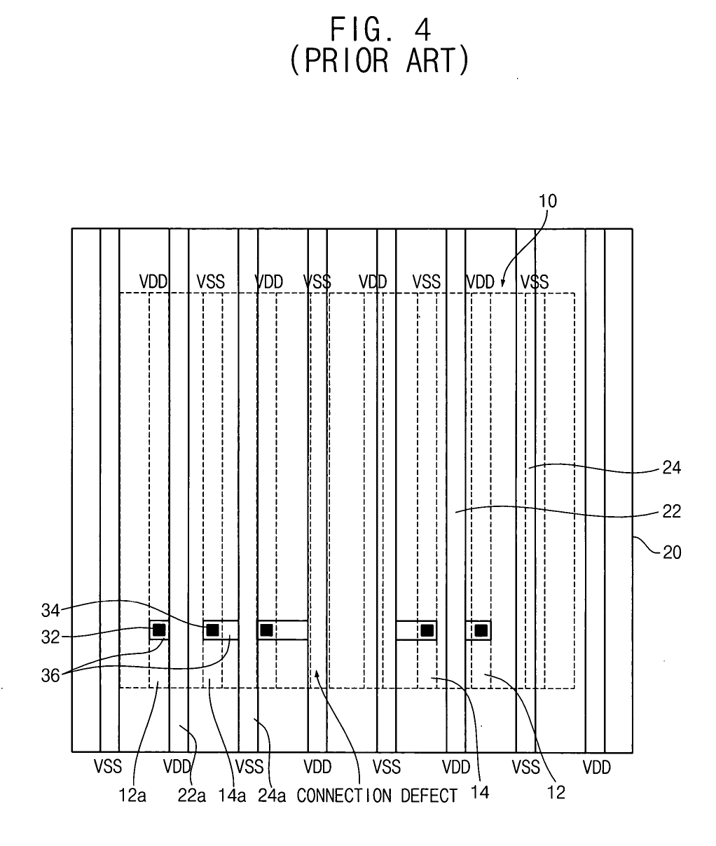

FIG. 5 is a wiring diagram illustrating a power line layout of a macro cell according to some embodiments of the present invention;

FIG. 6 is a wiring diagram illustrating a power line layout of the macro cell shown in FIG. 5 overlaid by a power mesh according to some embodiments of the present invention;

FIG. 7 is a wiring diagram illustrating a power line layout of a macro cell that is rotated by 90 degrees in a counterclockwise direction compared with FIG. 5 overlaid by a power mesh according to some embodiments of the present invention;

FIG. 8 is a wiring diagram illustrating a power line layout of a macro cell according to further embodiments of the present invention;

FIG. 9 is a wiring diagram illustrating a power line layout of a macro cell shown in FIG. 8 overlaid by a power mesh according to some embodiments of the present invention; and

FIG. 10 is a wiring diagram illustrating a power line layout of a macro cell that is rotated by 90 degrees in a clockwise direction compared with FIG. 8 overlaid by a power mesh according to some embodiments of the present invention.

### DETAILED DESCRIPTION OF EMBODIMENTS

While the invention is susceptible to various modifications and alternative forms, specific embodiments thereof are shown by way of example in the drawings and will herein be described in detail. It should be understood, however, that there is no intent to limit the invention to the particular forms disclosed, but on the contrary, the invention is to cover all modifications, equivalents, and alternatives falling within the spirit and scope of the invention as defined by the claims. Like reference numbers signify like elements throughout the description of the figures.

As used herein, the singular forms “a,” “an,” and “the” are intended to include the plural forms as well, unless expressly stated otherwise. It will be further understood that the terms “includes,” “comprises,” “including,” and/or “comprising,” when used in this specification, specify the presence of stated features, integers, steps, operations, elements, and/or components, but do not preclude the presence or addition of one or more other features, integers, steps, operations, elements, components, and/or groups thereof. It will be understood that when an element is referred to as being “connected” or “coupled” to another element, it can be directly connected or coupled to the other element or intervening elements may be present. Furthermore, “connected” or “coupled” as used herein may include wirelessly connected or coupled. As used herein, the term “and/or” includes any and all combinations of one or more of the associated listed items.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

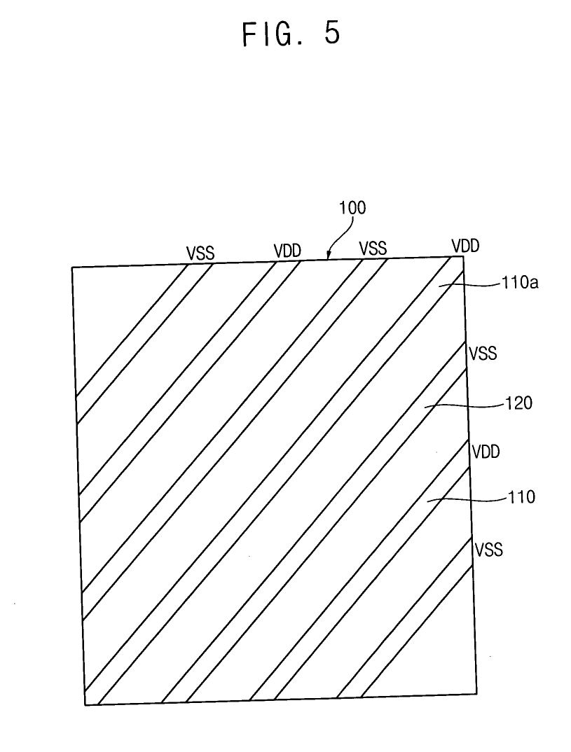

FIG. 5 is a wiring diagram illustrating a power line layout of a macro cell according to first example embodiments of the present invention. Referring to FIG. 5, to form a primary power line for providing a power voltage to a plurality of circuit elements (not shown) included in the macro cell 100 of a tetragon, a plurality of power lines 110 and 120 are diagonally arranged on the macro cell 100.

The plurality of power lines 110 and 120 include VDD lines 110 and VSS lines 120, which are alternately arranged in parallel with each other. A distance between the respective VDD lines 110 and the VSS lines 120 is generally uniform.

A center power line 110a may be formed from a first apex (or a first vertex) of the macro cell 100 to a second apex (or a second vertex) opposite to the first apex (or the first vertex) in a diagonal direction, and other power lines 110 and 120, except the center power line 110a, are spaced apart from the center power line 110a by a predetermined distance. The power lines 110 and 120 are generally parallel to the center power line 110a.

When a macro cell 100 having such a power line layout is combined with a power mesh, although the macro cell 100 is rotated, intersections between the power lines 110, 120 of the macro cell 100 and power lines of the power mesh always exist.

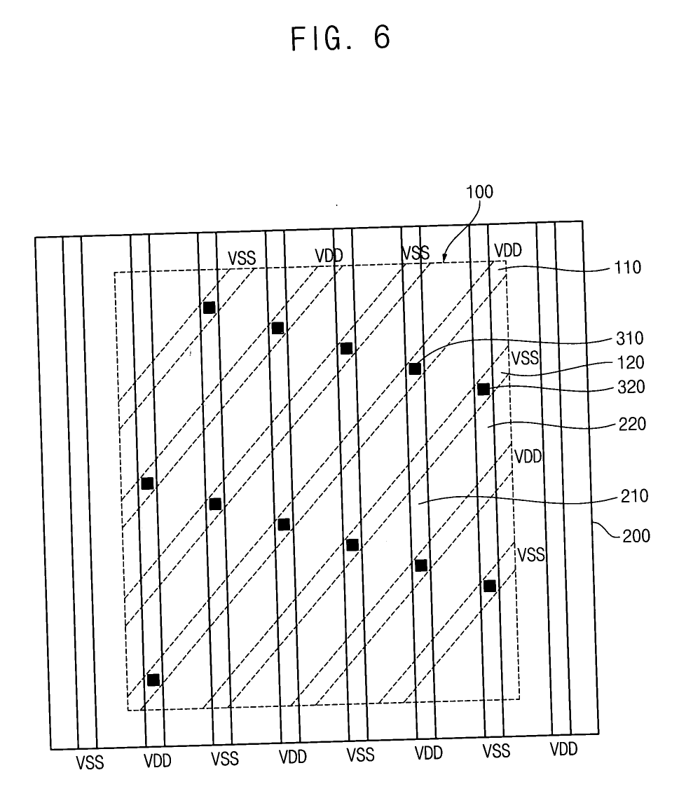

FIG. 6 is a wiring diagram illustrating a power line layout of a macro cell 100 shown in FIG. 5 overlaid by a power mesh 200. Referring to FIG. 6, VDD lines 210 and VSS lines 220 of the power mesh 200, which are coupled to each of the VDD line and the VSS line of an external power source (not shown), are alternatively arranged in a vertical direction with generally uniform intervals.

When the power mesh 200 is arranged on the macro cell 100, because the VDD lines 110 and the VSS lines 120 of the macro cell 100 are arranged in a diagonal direction, and the VDD lines 210 and the VSS lines 220 of the power mesh 200 are arranged in a vertical direction, VDD intersections 310 are formed between the VDD lines 110 of the macro cell 100 and the VDD lines 210 of the power mesh 200 that is disposed on the macro cell 100, and VSS intersections 320 are formed between the VSS lines 120 of the macro cell 100 and the VSS lines 220 of the power mesh 200 that is disposed on the macro cell 100.

That is, the VDD intersections 310 are formed between the VDD lines 110 arranged on the macro cell 100 in a diagonal direction and the VDD lines 210 arranged on the power mesh 200 in a vertical direction. Similarly, the VSS intersections 320 are formed between the VSS lines 120 arranged on the macro cell 100 in the diagonal direction and the VSS lines 220 arranged on the power mesh 200 in the vertical direction.

The VDD lines 110 and 210 forming the VDD intersections 310 may be coupled to each other in a stacked via-connection. The VSS lines 120 and 220 forming the VSS intersections 320 are coupled to each other in a stacked via-connection. Due to the stacked via-connection between the macro cell 100 and the power mesh 200, the power lines 210, 220 of the power mesh 200 and the power lines 110,120 of the macro cell 100 are electrically coupled to each other without special connection lines; thus, it is possible to provide a power voltage to the macro cell 100 from the power mesh 200.

Accordingly, it is not necessary to use special wiring for providing the power voltage to the macro cell 100; hence, the power voltage may be efficiently provided because a routing resource for wiring of various circuits may be obtained, as well as a simple circuit structure may be achieved.

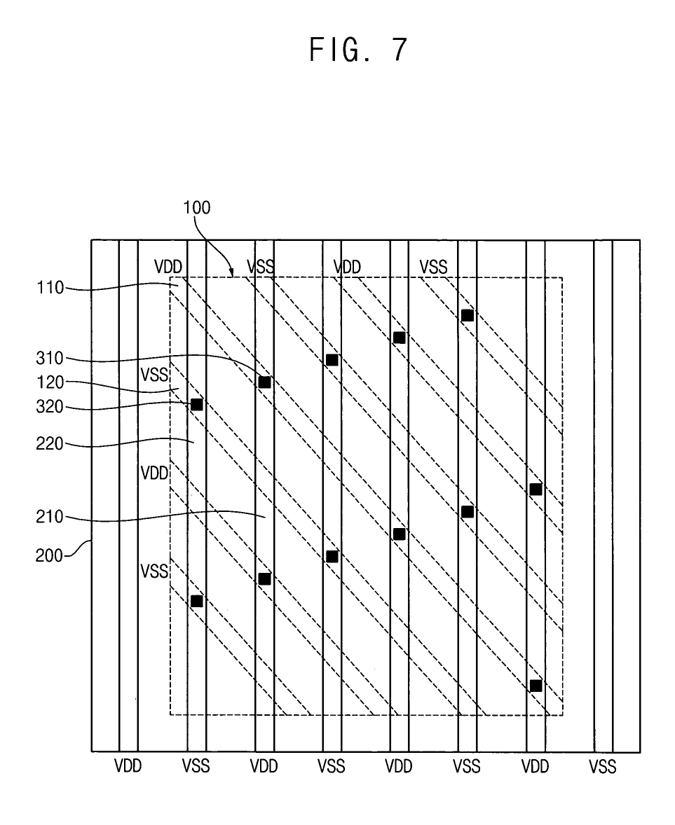

FIG. 7 is a wiring diagram illustrating a power line layout of a macro cell 100 that is rotated by 90 degrees in a counterclockwise direction compared with FIG. 5, which is overlaid by a power mesh. Referring to FIG. 7, VDD lines 110 and VSS lines 120 of the macro cell 100 are arranged in a diagonal direction. As a result, although the macro cell 100 is rotated, the diagonal shape of the power lines 110 and 120 of the macro cell 100 is not changed, but the VDD lines 110 and the VSS lines 120 take a different position and direction.

Consequently, the VDD intersections 310 are formed between the VDD lines 110 arranged on the macro cell 100 in a diagonal direction and the VDD lines 210 arranged on the power mesh 200 in a vertical direction. Similarly, the VSS intersections 320 are formed between the VSS lines 120 arranged on the macro cell 100 in the diagonal direction and the VSS lines 220 arranged on the power mesh 200 in the vertical direction.

The VDD lines 110 and 210 forming the VDD intersections 310 may be coupled to each other in a stacked via-connection. The VSS lines 210 and 220 forming the VSS intersections 320 may be coupled to each other in the stacked via-connection. Due to the stacked via-connection between the macro cell 100 and the power mesh 200, the power lines 210, 220 of the power mesh 200 and the power lines 110, 120 of the macro cell 100 are electrically-coupled to each other without special connection lines; thus, it is possible to provide a power voltage to the macro cell 100 from the power mesh 200.

The diagonal layout of the macro cell 100, according to the first example embodiments of the present invention, is applied to a second example embodiments described below.

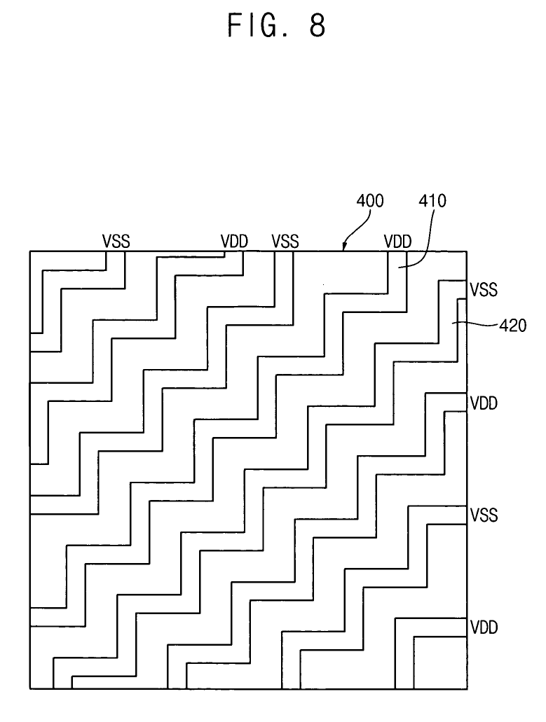

FIG. 8 is a wiring diagram illustrating a power line layout of a macro cell 400 according to second example embodiments of the present invention. Referring to FIG. 8, to form a primary power line for providing a power voltage to a plurality of circuit elements (not shown) included in the macro cell 400 of a tetragon, a plurality of power lines 410 and 420 are diagonally arranged on the macro cell 400. The plurality of power lines 410 and 420 are formed in a stair configuration having a plurality of step heights. An interior angle of the step height is about 90 degrees. The step height features an orthogonal shape and the step height lengths are substantially identical in accordance with some embodiments of the present invention.

The power lines 410 and 420 include VDD lines 410 and VSS lines 420, which are alternately arranged in parallel with each other such that a distance between the VDD lines 410 and the VSS lines 420 is generally uniform in accordance with some embodiments of the present invention.

When the macro cell 400 having the power line layout is combined with a power mesh, although the macro cell 400 is rotated, intersections between the power lines 410, 420 of the macro cell 400 and power lines of the power mesh always exist.

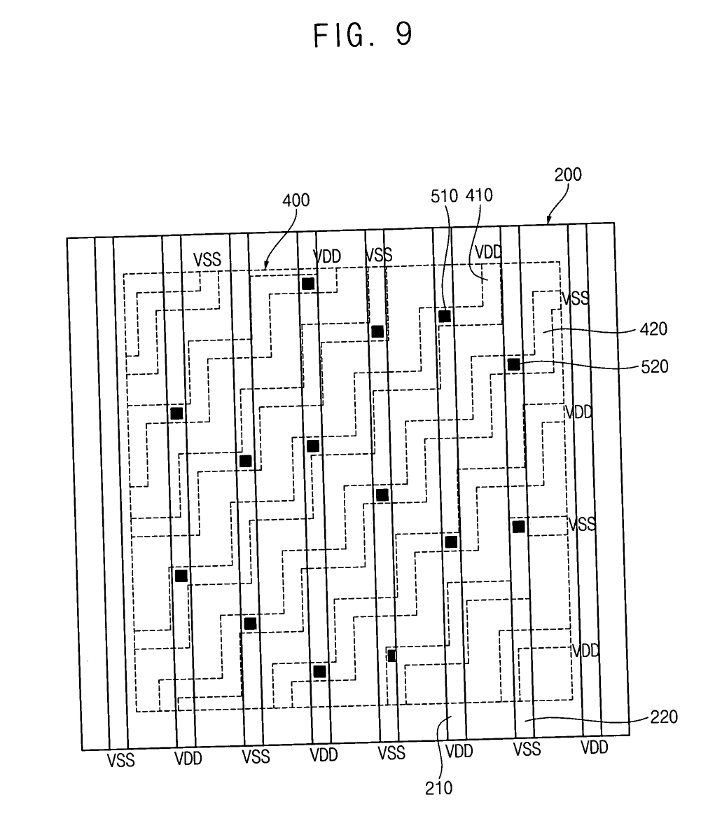

FIG. 9 is a wiring diagram illustrating a power line layout of a macro cell 400 shown in FIG. 8 overlaid by a power mesh 200. Referring to FIG. 9, when the power mesh 200 is arranged on the macro cell 400, VDD lines 410 and VSS lines 420 of the macro cell 400 are diagonally arranged in a stair configuration, and VDD lines 210 and VSS lines of the power mesh 200 are arranged in a vertical direction. As a result, intersections 510 and 520 are formed between the power lines 410, 420 of the macro cell 400 and the power lines 210, 220 of the power mesh 200 that is disposed on the macro cell 400.

That is, the VDD intersections 510 are formed between the VDD lines 410 diagonally arranged on the macro cell 400 in the stair configuration and the VDD lines 210 arranged on the power mesh 200 in the vertical direction, and the VSS intersections 520 are formed between the VSS lines 420 of the macro cell 400 and the VSS lines 220 of the power mesh 200.

The VDD lines 210 and 410 forming the VDD intersections 510 are coupled to each other in a stacked via-connection. The VSS lines 220 and 420 forming the VSS intersections 520 are coupled to each other in a stacked via-connection. Due to the stacked via-connections between the macro cell 400 and the power mesh 200, the power lines 210, 220 of the power mesh 200 and the power lines 410, 420 of the macro cell 400 are electrically coupled to each other; thus, it is possible to provide a power voltage to the macro cell 400 from the power mesh 200.

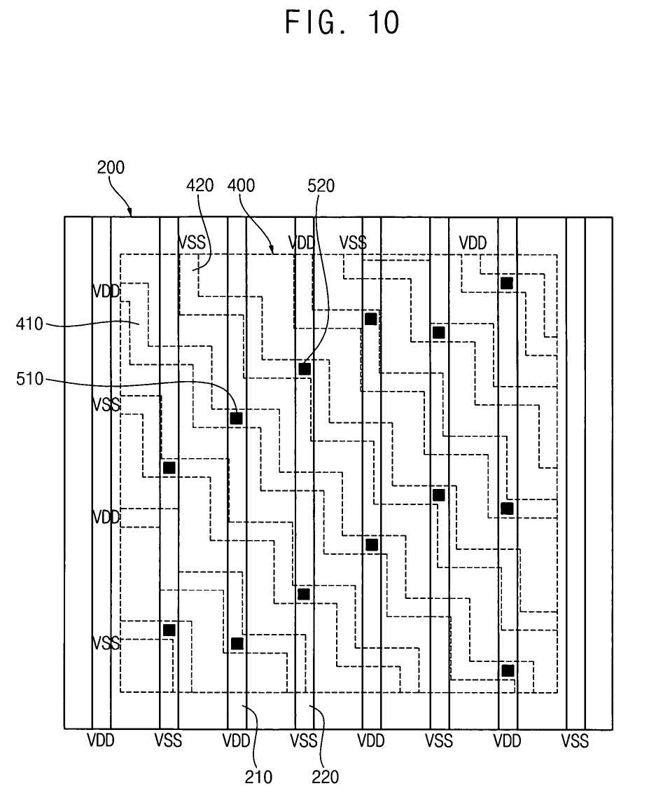

FIG. 10 is a wiring diagram illustrating a power line layout of a macro cell 400 that is rotated by 90 degrees in a clockwise direction compared with FIG. 8, which is overlaid by a power mesh 200. Referring to FIG. 10, VDD lines 410 and VSS lines 420 of the macro cell 400 are diagonally arranged in a stair configuration. As a result, although the macro cell 400 is rotated, the diagonal shape of the power lines 410 and 420 of the macro cell 400 is not changed, but the VDD lines 410 and the VSS lines 420 take a different position and direction.

Consequently, VDD intersections 510 are formed between the VDD lines 410 arranged on the macro cell 400 and the VDD lines 210 arranged on the power mesh 200. Similarly, VSS intersections 520 are formed between the VSS lines 420 arranged on the macro cell 400 and the VSS lines 220 arranged on the power mesh 200.

The VDD lines 210 and 410 forming the VDD intersections 510 are coupled to each other in a stacked via-connection. The VSS lines 220 and 420 forming the VSS intersections 520 are coupled to each other in a stacked via-connection. Due to the stacked via-connections between the macro cell 400 and the power mesh 200, the power lines 210, 220 of the power mesh 200 and the power lines 410, 420 of the macro cell 400 are electrically coupled to each other without special connection lines; thus, it is possible to provide a power voltage to the macro cell 400 from the power mesh 200.

In the first and second exemplary embodiments of the present invention described above, when the power lines are diagonally arranged on the macro cell or are diagonally arranged on the macro cell in a stair configuration, there is a high probability that intersections between the power lines occur.

Thus, an amount of separate wiring for providing the power voltage to the macro cell may be reduced and the power voltage may be efficiently provided because a routing resource for wiring of various circuits may be obtained. Additionally, connection defects may be reduced.

As described above, in the power line layouts of the macro cell, and combined layout of the macro cell and the power mesh using the power line layouts of the macro cell according to exemplary embodiments of the present invention, when the power lines of the macro cell are arranged on the power lines of the power mesh, the intersections are always formed between the power lines of the macro cell and the power mesh.

Therefore, each of the power lines may be coupled to each other in a stacked via-connection; thus, the combined layout between the power lines may be simplified because separate connection lines used in the conventional layout are not necessary. Hence, a power voltage may be efficiently provided because a routing resource for wiring of various circuits may be obtained. Additionally, connection defects may be reduced.

In a power line layout of a macro cell and a combined layout of a macro cell and a power mesh according to some embodiments of the present invention, the intersections between the power lines of the macro cell and the power lines of the power mesh are always formed when the power lines of the macro cell and the power lines of the power mesh are coupled.

Because the power lines may be coupled to each other in a stacked via-connection, the combined lay out between the power lines may be simplified without using conventional separate connection lines. In addition, a routing space for lines other than the power lines may be secured, and connection defects may be reduced.

In concluding the detailed description, it should be noted that many variations and modifications can be made to the embodiments without substantially departing from the principles of the present invention. All such variations and modifications are intended to be included herein within the scope of the present invention, as set forth in the following claims.

That which is claimed:

1. A power line layout of a macro cell, comprising:
a plurality of power lines arranged on a plane of the macro cell in a diagonal direction such that the power lines are substantially parallel with a line defined by two non-adjacent corners of the plane.

2. The power line layout of the macro cell of claim 1, wherein the power lines comprise VDD lines and VSS lines that alternate with respect to each other.

3. The power line layout of the macro cell of claim 1, wherein the power lines are substantially parallel to each other.

4. The power line layout of the macro cell of claim 1, wherein a distance between the power lines is substantially uniform.

5. The power line layout of the macro cell of claim 1, wherein the macro cell has a tetragonal shape.

6. The power line layout of the macro cell of claim 5, wherein the power lines comprise:
a center power line formed from a first vertex of the macro cell to a second vertex, non-adjacent to the first vertex, in a diagonal direction; and
other power lines spaced apart from both sides of the center power line by a predetermined distance and being substantially parallel with the center power line.

7. The power line layout of the macro cell of claim 1, wherein the power lines have a stair configuration having a plurality of step heights.

8. The power line layout of the macro cell of claim 7, wherein the step heights are substantially equal.

9. The power line layout of the macro cell of claim 7, wherein the stair configuration has an orthogonal shape of which an interior angle is about 90 degrees.

10. A combined layout of a macro cell and a power mesh, comprising:
a power mesh comprising a plurality of first power lines arranged a first direction; and
a macro cell comprising a plurality of internal circuit elements, a plurality of second power lines for providing a power voltage to the plurality of internal circuit elements, the plurality of second power lines being arranged on a plane of the macro cell in a diagonal direction such that the power lines are substantially parallel with a line defined by two non-adjacent corners of the plane;
wherein the first power lines are electrically coupled to the second power lines at intersections between the first power lines of the power mesh and the second power lines of the macro cell.

11. The combined layout of the macro cell and the power mesh of claim 10, wherein the second power lines of the macro cell comprise VDD lines and VSS lines that alternate with respect to each other.

12. The combined layout of the macro cell and the power mesh of claim 11, wherein the first power lines of the power mesh comprise VDD lines and VSS lines that alternate with respect to each other.

13. The combined layout of the macro cell and the power mesh of claim 12, wherein the intersections comprise:
VDD intersections where the VDD lines of the macro cell intersect with the VDD lines of the power mesh; and
VSS intersections where the VSS lines of the macro cell intersect with the VSS lines of the power mesh.

14. The combined layout of the macro cell and the power mesh of claim 13, wherein the VDD lines of the macro cell are coupled to the VDD lines of the power mesh at the VDD intersections.

15. The combined layout of the macro cell and the power mesh of claim 13, wherein the VSS lines of the macro cell are coupled to the VSS lines of the power mesh at the VSS intersections.

16. The combined layout of the macro cell and the power mesh of claim 10, wherein the first power lines of the power mesh and the second power lines of the macro cell are coupled to each other in a stacked via-connection.

17. The combined layout of the macro cell and the power mesh of claim 10, wherein the second power lines of the macro cell are substantially parallel to each other.

18. The combined layout of the macro cell and the power mesh of claim 10, wherein the first power lines of the power mesh are substantially parallel to each other.

19. The combined layout of the macro cell and the power mesh of claim 10, wherein a distance between the second power lines of the macro cell is substantially uniform.

20. The combined layout of the macro cell and the power mesh of claim 10, wherein a distance between the first power lines of the power mesh is substantially uniform.

21. The combined layout of the macro cell and the power mesh of claim 10, wherein the macro cell has a tetragonal shape.

22. The combined layout of the macro cell and the power mesh of claim 21, wherein the second power lines comprise:
a center power line formed from a first vertex of the macro cell to a second vertex, non-adjacent to the first vertex, in a diagonal direction; and
other power lines spaced apart from both sides of the center power line by a predetermined distance and being substantially parallel to the center power line.

23. The combined layout of the macro cell and the power mesh of claim 10, wherein the second power lines of the macro cell have a stair configuration having a plurality of step heights.

24. The combined layout of the macro cell and the power mesh of claim 23, wherein the step heights are substantially equal.

25. The combined layout of the macro cell and the power mesh of claim 23, wherein the stair configuration has an orthogonal shape of which an interior angle is about 90 degrees.

26. The combined layout of the macro cell and the power mesh of claim 10, wherein the macro cell is arranged in one of an upper layer and a lower layer of the power mesh.

27. The combined layout of the macro cell and the power mesh of claim 10, wherein the macro cell is configured to rotate so as to overlap with a plane of the power mesh.
